(19) United States
(12) Patent Application Publication
(10) Pub. No.: US 2025/0091858 A1
(43) Pub. Date: Mar. 20, 2025

(54) SANDWICH STRUCTURES FOR MICROELECTROMECHANICAL SYSTEM MICRO-MIRRORS

(71) Applicant: Infineon Technologies AG, Neubiberg (DE)

(72) Inventors: Theresa LUTZ, Göttingen (DE); Malika BELLA, Ottobrunn (DE); Stephan Gerhard ALBERT, München (DE); Andre BROCKMEIER, Villach (AT); Mohanraj SOUNDARA PANDIAN, Unterschleißheim (DE); Thomas BEVER, München (DE)

(21) Appl. No.: 18/822,580

(22) Filed: Sep. 3, 2024

Related U.S. Application Data
(60) Provisional application No. 63/583,314, filed on Sep. 18, 2023.

(51) Int. Cl. B81B 3/00; B81C 1/00

(52) U.S. Cl. CPC B81B 3/007; B81C 1/00658; B81B 2201/042; B81B 2203/0154; B81B 2203/0315; B81C 2201/013

(57) ABSTRACT

A microelectromechanical system (MEMS) mirror device includes a frame that defines a frame cavity; a suspension assembly; and a mirror body coupled to the frame by the suspension assembly such that the mirror body is suspended over the frame cavity. The mirror body comprises a sandwich structure that includes a front plate, a back plate, and a hollow core assembly arranged between the front plate and the back plate. The front plate and the back plate define a thickness dimension of the mirror body. The hollow core assembly includes a plurality of support structures that extend between the front plate and the back plate and define a plurality of cavities between the front plate and the back plate.

### CROSS-REFERENCE TO RELATED APPLICATION

This Patent Application claims priority to U.S. Provisional Patent Application No. 63/583,314, filed on Sep. 18, 2023, entitled “SANDWICH STRUCTURES FOR MICROELECTROMECHANICAL SYSTEM MICRO-MIRRORS,” which is hereby expressly incorporated by reference herein.

### BACKGROUND

A scanning system may use two-dimensional scanning to scan one or more light beams within a field-of-view (FOV) according to a scanning pattern. The scanning system may use two scanning axes, including a first scanning axis that is configured to steer the one or more light beams in a first direction at a first scanning frequency and a second scanning axis that is configured to steer the one or more light beams in a second direction at a second scanning frequency. The second scanning axis is typically perpendicular to the first scanning axis. Different scanning patterns can be obtained by using different fixed frequency ratios between the first scanning frequency and the second scanning frequency. Synchronizing the first scanning frequency and the second scanning frequency to maintain a fixed frequency ratio is important to maintain a particular scanning pattern during a scanning operation.

### SUMMARY

In some implementations, a microelectromechanical system (MEMS) mirror device includes a frame that defines a frame cavity; a suspension assembly; and a mirror body coupled to the frame by the suspension assembly such that the mirror body is suspended over the frame cavity, wherein the mirror body comprises a sandwich structure that includes a front plate, a back plate, and a hollow core assembly arranged between the front plate and the back plate, wherein the front plate and the back plate define a thickness dimension of the mirror body, and wherein the hollow core assembly includes a plurality of support structures that extend between the front plate and the back plate and define a plurality of cavities between the front plate and the back plate.

In some implementations, an oscillator device includes a frame that defines a frame cavity; a suspension assembly; and an oscillator body coupled to the frame by the suspension assembly such that the oscillator body is suspended over the frame cavity, wherein the oscillator body is configured to oscillate about one or more rotational axes, wherein the oscillator body comprises a sandwich structure that includes a front plate, a back plate arranged opposite to the front plate, and a hollow core assembly arranged between the front plate and the back plate, wherein the hollow core assembly includes a plurality of support structures that extend between the front plate and the back plate and define a plurality of cavities between the front plate and the back plate, and wherein the hollow core assembly is configured to reduce a dynamic deformation of the oscillator body during oscillation of the oscillator body about the one or more rotational axes and enable the oscillator body to oscillate at a resonant frequency that is greater than 10 kHz.

### BRIEF DESCRIPTION OF THE DRAWINGS

Implementations are described herein making reference to the appended drawings.

FIG. 1A is a schematic block diagram of a two-dimensional (2D) scanning system according to one or more implementations.

FIG. 1B is a schematic block diagram of a 2D scanning system according to one or more implementations.

FIG. 2A shows a front side and a back side of a MEMS mirror device according to one or more implementations.

FIG. 2B shows cross-sections of the MEMS mirror device according to one or more implementations.

FIG. 3A shows a plan view (top view) of a first hollow core assembly of a MEMS mirror device according to one or more implementations.

FIG. 3B shows a plan view (top view) of a second hollow core assembly of a MEMS mirror device according to one or more implementations.

FIG. 3C shows a plan view (top view) of a third hollow core assembly of a MEMS mirror device according to one or more implementations.

FIG. 3D shows a plan view (top view) of a fourth hollow core assembly of a MEMS mirror device according to one or more implementations.

FIG. 4A shows a cross-section of a MEMS mirror device according to one or more implementations.

FIG. 4B shows a cross-section of a MEMS mirror device according to one or more implementations.

FIG. 4C shows a cross-section of a MEMS mirror device according to one or more implementations.

FIG. 4D shows a cross-section of a MEMS mirror device according to one or more implementations.

FIGS. 5A-5D show a process flow directed to a method of manufacturing a MEMS mirror device according to one or more implementations.

FIGS. 6A and 6B show a process flow directed to a method of manufacturing a MEMS mirror device according to one or more implementations.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view, rather than in detail, in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually interchangeable.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “top,” “bottom,” “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling (e.g., any connection or coupling without additional intervening elements) may also be implemented by an indirect connection or coupling (e.g., a connection or coupling with one or more additional intervening elements, or vice versa) as long as the general purpose of the connection or coupling (e.g., to transmit a certain kind of signal or to transmit a certain kind of information) is essentially maintained. Features from different implementations may be combined to form further implementations. For example, variations or modifications described with respect to one of the implementations may also be applicable to other implementations unless noted to the contrary.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, a signal with an approximate signal value may practically have a signal value within 5% of the approximate signal value.

In the present disclosure, expressions including ordinal numbers, such as “first”, “second”, and/or the like, may modify various elements. However, such elements are not limited by such expressions. For example, such expressions do not limit the sequence and/or importance of the elements. Instead, such expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

A microelectromechanical system (MEMS) mirror can be driven about two or more scanning axes for use as a scanning device. Alternatively, two MEMS mirrors driven about a respective scanning axis may be optically coupled to form a scanning system. A MEMS mirror-based light beam scanner is one way to implement image projection technologies and object detection technologies such as Light Detection and Ranging (LIDAR). These technologies may rely on a two-dimensional (2D) scanning pattern, such as a Lissajous scanning pattern, that relies on accurately synchronized scanning axes driven at scanning frequencies that have a fixed frequency ratio.

Scanning speed and optical resolution are critical performance criteria for display applications and image projection technologies. Resonating MEMS micro-mirrors for high-definition display applications are required to operate at high frequencies (e.g., frequencies greater than 10 kHz, greater than 15 kHz, or even greater than 20 kHz). Additionally, the resonating MEMS micro-mirrors may be required to reach maximum tilt amplitudes that are greater than 10° in order to obtain a desired projection range or field-of-view.

Driving a resonating MEMS micro-mirror at high frequencies greater than 10 kHz and at maximum tilt amplitudes greater than 10° may be difficult to achieve depending on a mass of a mirror plate of the resonating MEMS micro-mirror. In order words, the higher the mass, the more difficult it may be to achieve resonant frequencies greater than 10 kHz at maximum tilt amplitudes greater than 10°. Thus, the mirror plate should be made as light as possible to reduce an inertia of the mirror plate during resonance in order to enable resonant frequencies greater than 10 kHz and maximum tilt amplitudes greater than 10°. However, lighter mirror plates are typically less rigid or stiff than heavier mirror plates. As a result, lighter mirror plates may be more susceptible to dynamic deformation than heavier mirror plates. Thus, obtaining a desired optical resolution with a combination of driving a resonating MEMS micro-mirror at high frequencies greater than 10 KHz and maximum tilt amplitudes greater than 10° may be difficult to achieve. For example, the combination of driving a resonating MEMS micro-mirror at high frequencies greater than 10 KHz and maximum tilt amplitudes greater than 10° may result in high acceleration loads on the mirror plate. In this case, high acceleration loads may lead to significant deformation of the mirror plate (dynamic deformation), which can have a negative impact on the optical resolution. Thus, a mirror plate should be sufficiently stiff to prevent dynamic deformation to obtain the desired optical resolution, but sufficiently lightweight to enable resonant frequencies greater than 10 kHz at maximum tilt amplitudes greater than 10°.

Some implementations disclosed herein are directed to a MEMS micro-mirror having a mirror body that is constructed as a sandwich structure that includes two face plates with a hollow core assembly in between the two face plates. Such a construction forms a lightweight and stiff mirror body, which in turns enables the mirror body to be operated at high frequencies due to the mirror body's reduced mass. Additionally, the sandwich structure prevents or reduces deformation (e.g., caused by dynamic deformation) that may otherwise occur from high oscillation speeds and/or large maximum tilt angles. Thus, the MEMS micro-mirror may be operated at high frequencies without being compromised by dynamic deformation. As a result, higher optical resolutions can be achieved with the MEMS micro-mirror. For example, the hollow core assembly may enable the mirror body to oscillate at a resonant frequency greater than 10 kHz with reduced inertia and reduced dynamic deformation. Moreover, the hollow core assembly may enable the mirror body to oscillate a maximum tilt amplitude that is greater than 10°.

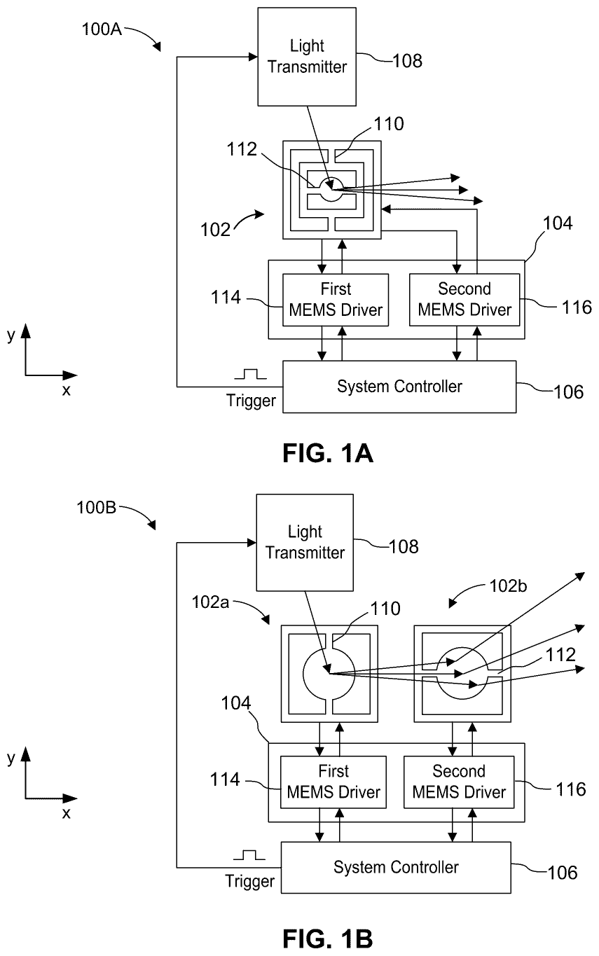

FIG. 1A is a schematic block diagram of a 2D scanning system 100A, according to one or more implementations. In particular, the 2D scanning system 100A includes a MEMS mirror 102 implemented as a single scanning structure that is configured to steer or otherwise deflect light beams according to a 2D scanning pattern. The 2D scanning system 100A further includes a MEMS driver system 104, a system controller 106, and a light transmitter 108.

In the example shown in FIG. 1A, the MEMS mirror 102 is a mechanical moving mirror (e.g., a MEMS micro-mirror) integrated on a semiconductor chip (not shown). The MEMS mirror 102 is configured to rotate or oscillate via rotation about two scanning axes (e.g., two rotational axes) that are typically orthogonal to each other. For example, the two scanning axes may include a first scanning axis 110 that enables the MEMS mirror 102 to steer light in a first scanning direction (e.g., an x-direction) and a second scanning axis 112 that enables the MEMS mirror 102 to steer light in a second scanning direction (e.g., a y-direction). As a result, the MEMS mirror 102 can direct light beams in two dimensions according to the 2D scanning pattern, and may be referred to as a 2D MEMS mirror.

A scan can be performed to illuminate an area referred to as a field-of-view. The scan, such as an oscillating horizontal scan (e.g., from left to right and right to left of a field-of-view), an oscillating vertical scan (e.g., from bottom to top and top to bottom of a field-of-view), or a combination thereof (e.g., a Lissajous scan or a raster scan) can illuminate the field-of-view in a continuous scan fashion. In some implementations, the 2D scanning system 100A may be configured to transmit successive light beams (e.g., as successive light pulses) in different scanning directions to scan the field-of-view. In some implementations, the 2D scanning system 100A may be configured to transmit a continuous light beam (e.g., as a frequency-modulated continuous-wave (FMCW)) in different scanning directions to scan the field-of-view. In other words, the field-of-view can be illuminated by a scanning operation. In general, an entire field-of-view represents a scanning area defined by a full range of motion of the MEMS mirror 102. Thus, the entire field-of-view is delineated by a left edge, a right edge, a bottom edge, and a top edge. The entire field-of-view can also be referred to as a field of illumination or as a projection area in a projection plane onto which an image is projected.

The MEMS mirror 102 can direct a transmitted light beam at a desired 2D coordinate (e.g., an x-y coordinate) in the field-of-view. In some implementations, such as LIDAR implementations, the MEMS mirror 102 may be arranged to receive transmitted light beams from the light transmitter 108 and steer (scan) the transmitted light beams into the field-of-view to perform a scanning of the environment. The transmitted light beams may be backscattered by one or more objects back toward the 2D scanning system 100A as reflected light beams where the reflected light beams are detected by a sensor. For example, the sensor may be a photodetector array. The sensor may convert each reflected light beam into an electric signal (e.g., a current signal or a voltage signal) that may be further processed by the 2D scanning system 100A to generate object data or an image. In such implementations, the desired 2D coordinate may correspond to a particular transmission direction in the field-of-view that is targeted by the transmitted light beam for object detection, with different 2D coordinates corresponding to different transmission directions.

Alternatively, in some implementations, such as image projection systems, the desired 2D coordinate may correspond to an image pixel of a projected image, with different 2D coordinates corresponding to different image pixels of the projected image. In some implementations, an image projection system may include wearable augmented reality goggles, and the MEMS mirror 102 may be arranged to receive the transmitted light beams and steer (scan) the transmitted light beams onto a retina of a human eye in order to render an image thereon. In some implementations, an image projection system may include a head-up display (HUD) and the MEMS mirror 102 may be arranged to receive the transmitted light beams and steer (scan) the transmitted light beams onto a display screen.

Accordingly, multiple light beams transmitted at different transmission times or a continuous light beam can be steered by the MEMS mirror 102 at the different 2D coordinates of the field-of-view in accordance with the 2D scanning pattern. The MEMS mirror 102 can be used to scan the field-of-view in both scanning directions by changing an angle of deflection of the MEMS mirror 102 on each of the first scanning axis 110 and the second scanning axis 112.

A rotation of the MEMS mirror 102 about the first scanning axis 110 may be performed between two predetermined extremum deflection angles (e.g., +/−5 degrees, +/−15 degrees, etc.). Likewise, a rotation of the MEMS mirror 102 about the second scanning axis 112 may be performed between two predetermined extremum deflection angles (e.g., +/−5 degrees, +/−15 degrees, etc.). In some implementations, depending on the 2D scanning pattern, the two predetermined extremum deflection angles used for the first scanning axis 110 may be the same as the two predetermined extremum deflection angles used for the second scanning axis 112. In some implementations, depending on the 2D scanning pattern, the two predetermined extremum deflection angles used for the first scanning axis 110 may be different from the two predetermined extremum deflection angles used for the second scanning axis 112.

In some implementations, the MEMS mirror 102 can be a resonator (e.g., a resonant MEMS mirror) configured to oscillate side-to-side about the first scanning axis 110 at a first frequency (e.g., a first resonance frequency) and configured to oscillate top-to-bottom about the second scanning axis 112 at a second frequency (e.g., a second resonance frequency). Thus, the MEMS mirror 102 can be continuously driven about the first scanning axis 110 and the second scanning axis 112 to perform a continuous scanning operation. As a result, light beams reflected by the MEMS mirror 102 are scanned into the field-of-view in accordance with the 2D scanning pattern.

Different frequencies or a same frequency may be used for the first scanning axis 110 and the second scanning axis 112 for defining the 2D scanning pattern. For example, a raster scanning pattern or a Lissajous scanning pattern may be achieved by using different frequencies for the first frequency and the second frequency. Raster scanning and Lissajous scanning are two types of scanning that can be implemented in display applications, light scanning applications, and light steering applications, to name a few. As an example, Lissajous scanning is typically performed using two resonant scanning axes which are driven at different constant scanning frequencies with a defined fixed frequency ratio therebetween that forms a specific Lissajous pattern and frame rate. In order to properly carry out the Lissajous scanning and the raster scanning, synchronization of the two scanning axes is performed by the system controller 106 in conjunction with transmission timings of the light transmitter 108.

For each respective scanning axis, including the first scanning axis 110 and the second scanning axis 112, the MEMS mirror 102 includes an actuator structure used to drive the MEMS mirror 102 about the respective scanning axis. Each actuator structure may include interdigitated finger electrodes made of interdigitated mirror combs and frame combs to which a drive voltage (e.g., an actuation signal or driving signal) is applied by the MEMS driver system 104. Applying a difference in electrical potential between interleaved mirror combs and frame combs creates a driving force between the mirror combs and the frame combs, which creates a torque on a mirror body of the MEMS mirror 102 about the intended scanning axis. The drive voltage can be toggled between two voltages, resulting in an oscillating driving force. The oscillating driving force causes the MEMS mirror 102 to oscillate back and forth on the respective scanning axis between two extrema. Depending on the configuration, this actuation can be regulated or adjusted by adjusting a drive voltage off time, a voltage level of the drive voltage (e.g., a high-voltage (HV) level), or a duty cycle.

In other examples, the MEMS mirror 102 may use other actuation methods to drive the MEMS mirror 102 about the respective scanning axes. For example, these other actuation methods may include electromagnetic actuation, piezoelectric actuators, or thermal actuators. In electromagnetic actuation, the MEMS mirror 102 may be immersed in a magnetic field, and an alternating electric current through conductive paths may create the oscillating torque around the scanning axis. Piezoelectric actuators may be integrated in leaf springs of the MEMS mirror 102, or the leaf springs may be made of piezoelectric material to produce alternating beam bending forces in response to an electrical signal to generate the oscillation torque. Piezoelectricity is an electric charge that accumulates in certain solid materials and an electric potential is produced between opposite electrodes.

The MEMS driver system 104 is configured to generate driving signals (e.g., actuation signals) to drive the MEMS mirror 102 about the first scanning axis 110 and the second scanning axis 112. In particular, the MEMS driver system 104 is configured to apply the driving signals to the actuator structure of the MEMS mirror 102. In some implementations, the MEMS driver system 104 includes a first MEMS driver 114 configured to drive the MEMS mirror 102 about the first scanning axis 110 and a second MEMS driver 116 configured to drive the MEMS mirror 102 about the second scanning axis 112. In implementations in which the MEMS mirror 102 is used as an oscillator, the first MEMS driver 114 is configured to drive an oscillation of the MEMS mirror 102 about the first scanning axis 110 at the first frequency, and the second MEMS driver 116 is configured to drive an oscillation of the MEMS mirror 102 about the second scanning axis 112 at the second frequency.

The first MEMS driver 114 may be configured to sense a first rotational position of the MEMS mirror 102 about the first scanning axis 110 and provide first position information indicative of the first rotational position (e.g., tilt angle or degree of rotation about the first scanning axis 110) to the system controller 106. Similarly, the second MEMS driver 116 may be configured to sense a second rotational position of the MEMS mirror 102 about the second scanning axis 112 and provide second position information indicative of the second rotational position (e.g., tilt angle or degree of rotation about the second scanning axis 112) to the system controller 106.

The system controller 106 may use the first position information and the second position information to trigger light beams at the light transmitter 108. For example, the system controller 106 may use the first position information and the second position information to set a transmission time of light transmitter 108 in order to target a particular 2D coordinate of the 2D scanning pattern. Thus, a higher accuracy in position sensing of the MEMS mirror 102 by the first MEMS driver 114 and the second MEMS driver 116 may result in the system controller 106 providing more accurate and precise control of other components of the 2D scanning system 100A.

As noted above, the first MEMS driver 114 and the second MEMS driver 116 may apply a drive voltage to a corresponding actuator structure of the MEMS mirror 102 as the driving signal to drive a rotation (e.g., an oscillation) of the MEMS mirror 102 about a respective scanning axis (e.g., the first scanning axis 110 or the second scanning axis 112). The drive voltage can be switched or toggled between an HV level and a low-voltage (LV) level resulting in an oscillating driving force. In some implementations, the LV level may be zero (e.g., the drive voltage is off), but is not limited thereto and could be a non-zero value. When the drive voltage is toggled between an HV level and an LV level and the LV level is set to zero, it can be said that the drive voltage is toggled on and off (HV on/off). The oscillating driving force causes the MEMS mirror 102 to oscillate back and forth on the first scanning axis 110 or the second scanning axis 112 between two extrema. The drive voltage may be a constant drive voltage, meaning that the drive voltage is the same voltage when actuated (e.g., toggled on), or one or both of the HV level or the LV level of the drive voltage may be adjustable. However, it will be understood that the drive voltage is being toggled between the HV level and the LV level in order to produce the mirror oscillation. Depending on a configuration, this actuation can be regulated or adjusted by the system controller 106 by adjusting the drive voltage off time, a voltage level of the drive voltage, or a duty cycle. As noted above, frequency and phase of the drive voltage can also be regulated and adjusted.

In some implementations, the system controller 106 is configured to set a driving frequency of the MEMS mirror 102 for each scanning axis and is capable of synchronizing the oscillations about the first scanning axis 110 and the second scanning axis 112. In particular, the system controller 106 may be configured to control an actuation of the MEMS mirror 102 about each scanning axis by controlling the driving signals. The system controller 106 may control the frequency, the phase, the duty cycle, the HV level, and/or the LV level of the driving signals to control the actuations about the first scanning axis 110 and the second scanning axis 112. The actuation of the MEMS mirror 102 about a particular scanning axis controls its range of motion and scanning rate about that particular scanning axis.

For example, to make a Lissajous scanning pattern reproduce itself periodically with a frame rate frequency, the first frequency at which the MEMS mirror 102 is driven about the first scanning axis 110 and the second frequency at which the MEMS mirror 102 is driven about the second scanning axis 112 are different. A difference between the first frequency and the second frequency is set by a fixed frequency ratio that is used by the 2D scanning system 100A to form a repeatable Lissajous pattern (frame) with a frame rate. A new frame begins each time the Lissajous scanning pattern restarts, which may occur when a phase difference between a mirror phase about the first scanning axis 110 and a mirror phase about the second scanning axis 112 is zero. The system controller 106 may set the fixed frequency ratio and synchronize the oscillations about the first scanning axis 110 and the second scanning axis 112 to ensure that this fixed frequency ratio is maintained based on the first position information and the second position information received from the first MEMS driver 114 and the second MEMS driver 116, respectively.

The light transmitter 108 may include one or more light sources, such as one or more laser diodes or one or more light emitting diodes, for generating one or more light beams. In some implementations, the light transmitter 108 may be configured to sequentially transmit a plurality of light beams (e.g., light pulses) as the MEMS mirror 102 changes its transmission direction in order to target different 2D coordinates. The plurality of light beams may include visible light, infrared (IR) light, or other types of illumination signals, depending on an application of the 2D scanning system 100A. A transmission sequence of the plurality of light beams and a timing thereof may be implemented by the light transmitter 108 according to a trigger signal received from the system controller 106. Alternatively, in some implementations, the light transmitter 108 may be configured to transmit a continuous light beam as the MEMS mirror 102 changes its transmission direction in order to target different 2D coordinates. The continuous light beam may include visible light, IR light, or another type of illumination signal, depending on the application of the 2D scanning system 100A.

The system controller 106 is configured to control components of the 2D scanning system 100A. In certain applications, the system controller 106 may also be configured to receive programming information with respect to the 2D scanning pattern and control a timing of the plurality of light beams generated by the light transmitter 108 based on the programming information. Thus, the system controller 106 may include both processing and control circuity that is configured to generate control signals for controlling the light transmitter 108, the first MEMS driver 114, and the second MEMS driver 116.

The system controller 106 is configured to set the driving frequencies of the MEMS mirror 102 for the first scanning axis 110 and the second scanning axis 112 and is capable of synchronizing the oscillations about the first scanning axis 110 and the second scanning axis 112 to generate the 2D scanning pattern. In some implementations, in which the plurality of light beams is used, the system controller 106 may be configured to generate the trigger signal used for triggering the light transmitter 108 to generate the plurality of light beams. Using the trigger signal, the system controller 106 can control the transmission times of the plurality of light beams of the light transmitter 108 to achieve a desired illumination pattern within the field-of-view. The desired illumination pattern is produced by a combination of the 2D scanning pattern produced by the MEMS mirror 102 and the transmission times triggered by the system controller 106. In some implementations in which the continuous light beam is used, the system controller 106 may be configured to control a frequency modulation of the continuous light beam via a control signal provided to the light transmitter 108.

As indicated above, FIG. 1A is provided as an example. Other examples may differ from what is described with regard to FIG. 1A. In practice, the 2D scanning system 100A may include additional components, fewer components, different components, or differently arranged components than those shown in FIG. 1A without deviating from the disclosure provided above.

FIG. 1B is a schematic block diagram of a 2D scanning system 100B according to one or more implementations. In particular, the 2D scanning system 100B includes two MEMS mirrors, a first MEMS mirror 102a and a second MEMS mirror 102b, that are optically coupled in series to steer or otherwise deflect light beams according to a 2D scanning pattern. The first MEMS mirror 102a and the second MEMS mirror 102b are similar to the MEMS mirror 102 described in FIG. 1A, with the exception that the first MEMS mirror 102a and the second MEMS mirror 102b are each configured to rotate about a single scanning axis instead of two scanning axes. The first MEMS mirror 102a is configured to rotate about the first scanning axis 110 to steer light in the x-direction and the second MEMS mirror 102b is configured to rotate about the second scanning axis 112 to steer light in the y-direction. Similar to the MEMS mirror 102 described in FIG. 1A, the first MEMS mirror 102a and the second MEMS mirror 102b may be resonant MEMS mirrors configured to oscillate about the first scanning axis 110 and the second scanning axis 112, respectively.

Because each of the first MEMS mirror 102a and the second MEMS mirror 102bis configured to rotate about a single scanning axis, each of the first MEMS mirror 102a and the second MEMS mirror 102b is responsible for scanning light in one dimension. As a result, the first MEMS mirror 102a and the second MEMS mirror 102b may be referred to as one-dimensional (1D) MEMS mirrors. In the example shown in FIG. 1B, the first MEMS mirror 102a and the second MEMS mirror 102b are used together to steer light beams in two dimensions. The first MEMS mirror 102a and the second MEMS mirror 102b are arranged sequentially along a transmission path of the light beams such that one of the MEMS mirrors (e.g., the first MEMS mirror 102a) first receives a light beam and steers the light beam in a first dimension, and the other one of the MEMS mirrors (e.g., the second MEMS mirror 102b) receives the light beam from the first MEMS mirror 102a and steers the light beam in a second dimension. As a result, the first MEMS mirror 102a and the second MEMS mirror 102b operate together to steer the light beam generated by the light transmitter 108 in two dimensions. In this way, the first MEMS mirror 102a and the second MEMS mirror 102b can direct the light beam at a desired 2D coordinate (e.g., an x-y coordinate) in the field-of-view. Multiple light beams can be steered by the first MEMS mirror 102a and the second MEMS mirror 102b at different 2D coordinates of a 2D scanning pattern.

The MEMS driver system 104, the system controller 106, and the light transmitter 108 are configured to operate as similarly described above in reference to FIG. 1A. The first MEMS driver 114 is electrically coupled to the first MEMS mirror 102a to drive the first MEMS mirror 102a about the first scanning axis 110 and to sense a position of the first MEMS mirror 102a about the first scanning axis 110 to provide first position information to the system controller 106. Similarly, the second MEMS driver 116 is electrically coupled to the second MEMS mirror 102b to drive the second MEMS mirror 102b about the second scanning axis 112 and to sense a position of the second MEMS mirror 102b about the second scanning axis 112 to provide second position information to the system controller 106.

As indicated above, FIG. 1B is provided as an example. Other examples may differ from what is described with regard to FIG. 1B. In practice, the 2D scanning system 100B may include additional components, fewer components, different components, or differently arranged components than those shown in FIG. 1B without deviating from the disclosure provided above.

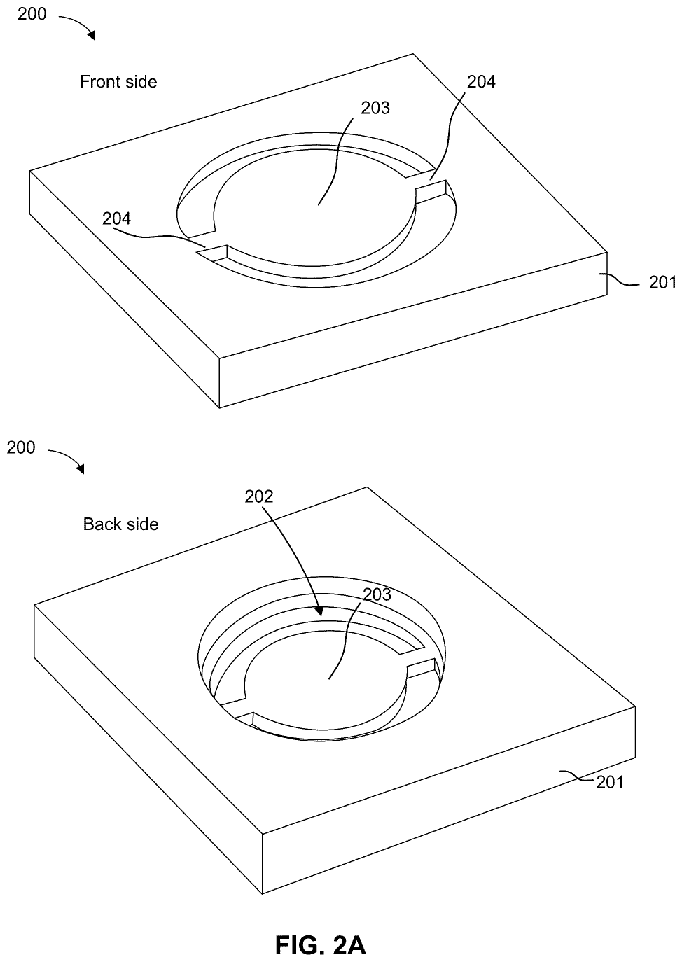

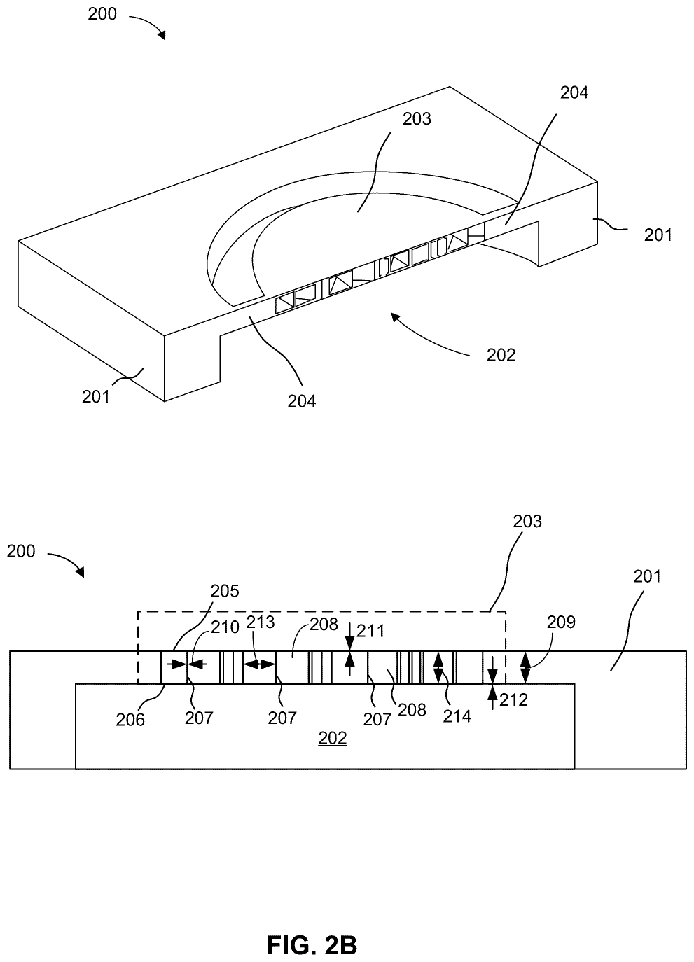

FIG. 2A shows a front side and a back side of a MEMS mirror device 200 according to one or more implementations. The MEMS mirror device 200 may include a frame 201 that is rotationally fixed. The frame 201 may be made of a semiconductor substrate. Additionally, the frame 201 may be structured to define a frame cavity 202 or frame recess over which a mirror body 203 is suspended by a suspension assembly. The suspension assembly is mechanically coupled to and between the frame 201 and the mirror body 203, and is configured to suspend the mirror body 203 over the frame cavity 202. Thus, the mirror body 203 is to the frame 201 by the suspension assembly such that the mirror body 203 is suspended over the frame cavity 202. In the example of FIG. 2A, the suspension assembly includes a pair of torsion bars 204 or beams that are mechanically coupled to and between the frame 201 and the mirror body 203. The pair of torsion bars 204 may extend, at least partially, along one of the scanning axes 110 or 112. The mirror body 203 may be configured to oscillate by an actuation mechanisms, such as piezoelectric, electric, thermal, or electromagnetic. In addition, the mirror body may have a sandwich structure that includes a front plate, a back plate, and a hollow core assembly arranged between the front plate and the back plate.

As indicated above, FIG. 2A is provided as an example. Other examples may differ from what is described with regard to FIG. 2A.

FIG. 2B shows cross-sections of the MEMS mirror device 200 according to one or more implementations. The mirror body 203 has a sandwich structure that includes two face plates, including a front plate 205 and a back plate 206, with hollow core assembly between the front plate 205 and the back plate 206. The front plate 205 and the back plate 206 define a thickness dimension 209 of the mirror body 203. The hollow core assembly may include a plurality of support structures 207 (e.g., vertical struts or support beams extending between the two face plates) that are spaced apart to define a plurality of cavities 208 between the front plate 205 and the back plate 206. The plurality of cavities 208 may be hollow internal areas arranged within an interior of the mirror body 203. In some implementations, the front plate 205, the back plate 206, and the hollow core assembly form a one-piece integral member.

The plurality of cavities 208 enable the mirror body 203 to be produced with reduced mass when compared with a solid mirror body. Meanwhile, the plurality of support structures 207 add rigidity and stiffness to the mirror body 203 to resist dynamic deformation. Thus, the hollow core assembly enables the mirror body 203 to be both lightweight for high resonant frequencies greater than 10 kHz and stiff enough to prevent dynamic deformation at the high resonant frequencies. Put another way, the hollow core assembly may enable the mirror body 203 to oscillate at a resonant frequency greater than 10 kHz with reduced inertia and reduced dynamic deformation. In some implementations, the plurality of support structures 207 may be configured to reduce the dynamic deformation of the mirror body 203 during oscillation of the mirror body 203 about the one or more rotational axes. Additionally, the plurality of support structures may be configured such that a volume of the plurality of cavities 208 enables the mirror body 203 to oscillate at a resonant frequency that is greater than 10 kHz. For example, the plurality of support structures 207 may be configured such that a mass of the plurality of support structures 207 enables the mirror body 203 to oscillate at a resonant frequency that is greater than 10 kHz with a maximum amplitude that is greater than 10°.

In some implementations, the thickness dimension 209 of the mirror body 203 is between 50-400 μm and each support structure of the plurality of support structures has a width dimension 210 between 5-100 μm. In some implementations, the front plate and the back plate each have a respective thickness dimension 211, 212 between 1-70 μm. In some implementations, each cavity 208 of the plurality of cavities has a width 213 between 2-400 μm. A ratio of the width dimension 210 and a thickness dimension 214 of each support structure 207 is in a range of 1:8 to 1:200, and more preferably in a range of 1:10 to 1:20. The above-described dimensions are important to ensuring the mirror body 203 is light enough to oscillate at a resonant frequency that is greater than 10 kHz with a maximum amplitude that is greater than 10°, while being stiff enough to prevent dynamic deformation or at least reduce dynamic deformation to be within an acceptable tolerance margin for achieving high optical resolution. Being outside of the above-described dimensions may result in the mirror body 203 being too heavy to achieve resonant frequency that is greater than 10 kHz and/or a maximum amplitude that is greater than 10°, or not sufficiently stiff to prevent dynamic deformation or to reduce dynamic deformation to be within the acceptable tolerance margin for achieving high optical resolution.

In some implementations, the plurality of support structures 207 may be interconnected to form a triangular pattern. The plurality of cavities 208 may be triangular cavities defined in areas between respective support structures of the plurality of support structures 207.

In some implementations, the plurality of support structures 207 may be interconnected to form a honeycomb pattern. The plurality of cavities 208 may be hexagonal cavities defined in areas between respective support structures of the plurality of support structures 207.

In some implementations, the plurality of support structures 207 may be interconnected to form a polygonal pattern. The plurality of cavities 208 may be polygonal cavities defined in areas between respective support structures of the plurality of support structures 207.

In some implementations, the plurality of support structures 207 may be vertical struts arranged to form a truss framework or a lattice pattern that is integrated into the mirror body 203.

In some implementations, cavities of the plurality of cavities 208 may be uniform in size throughout the hollow core assembly.

The mirror body 203 may be more susceptible to dynamic deformation in a central section than in a peripheral section. Thus, in some implementations, the plurality of cavities 208 include a first group of cavities arranged in a central section of the hollow core assembly and a second group of cavities may be arranged in a peripheral section of the hollow core assembly. Cavities of the first group of cavities may be smaller in size than cavities of the second group of cavities. As a result, the hollow core assembly may provide more rigidity or stiffness in the central section of the mirror body 203 compared to a rigidity or stiffness in the peripheral section of the mirror body 203 to reduce or prevent dynamic deformation where the dynamic deformation is most likely to occur.

In some implementations, a spacing of the plurality of support structures has a higher density in a central area of the mirror body than a relatively lower density in a peripheral area of the mirror body. As a result, the hollow core assembly may provide more rigidity or stiffness in the central are of the mirror body 203 compared to a rigidity or stiffness in the peripheral area of the mirror body 203.

In some implementations, the hollow core assembly has a higher mass in a central area of the mirror body 203 than a relatively lower mass in a peripheral area of the mirror body 203. As a result, the hollow core assembly may provide more rigidity or stiffness in the central section of the mirror body 203 compared to a rigidity or stiffness in the peripheral section of the mirror body 203.

In some implementations, cavities of the plurality of cavities arranged in a central area of the mirror body have smaller volumes relative to volumes of cavities of the plurality of cavities arranged in a peripheral area of the mirror body. As a result, the hollow core assembly may provide more rigidity or stiffness in the central section of the mirror body 203 compared to a rigidity or stiffness in the peripheral section of the mirror body 203

In some implementations, the back plate 206 may be a perforated back plate having a plurality of perforations that extend through the back plate 206. Each perforation of the plurality of perforations may be integrated with a respective cavity of the plurality of cavities 208. Each cavity of the plurality of cavities 208 is integrated with a respective perforation of the plurality of perforations. The perforations may be used to etch (e.g., to form) each cavity and may reduce the mass of the mirror body 203.

In some implementations, one or more stiffening support structures may be provided. The one or more stiffening support structures may be coupled to the back plate 206 and may extend from the back plate 206 into the frame cavity 202. The one or more stiffening support structures may be configured to reduce a dynamic deformation of the mirror body 203 during an oscillating operation.

As indicated above, FIG. 2B is provided as an example. Other examples may differ from what is described with regard to FIG. 2B.

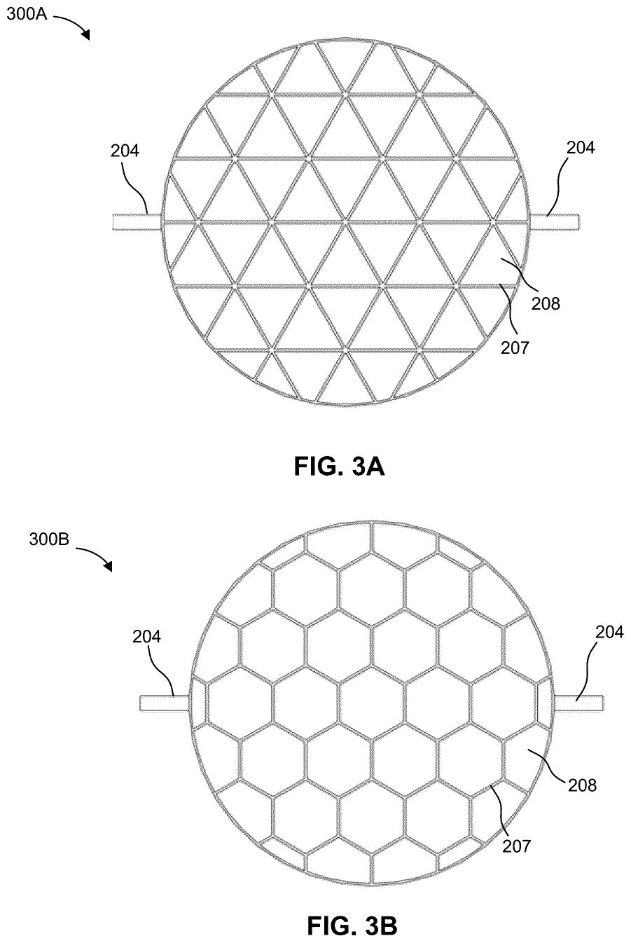

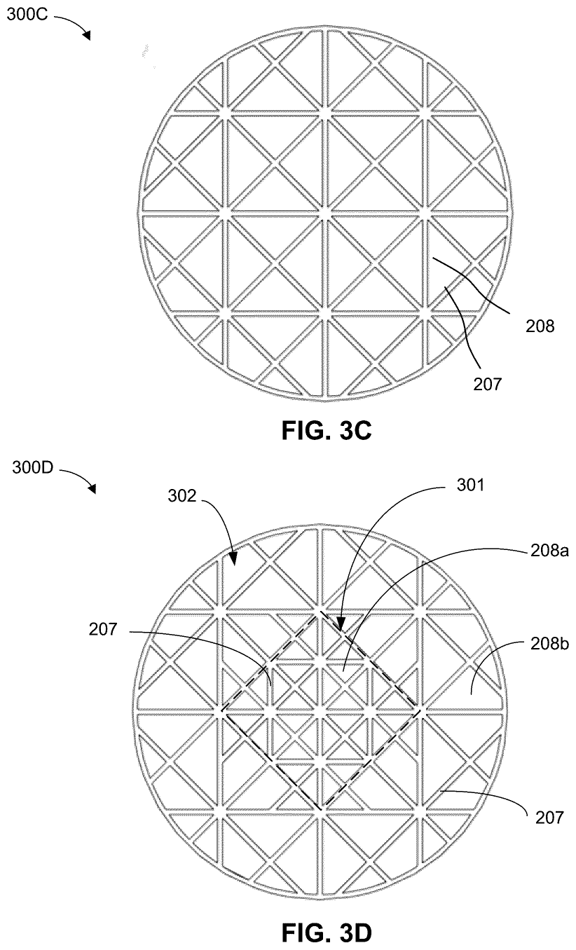

FIG. 3A shows a plan view (top view) of a first hollow core assembly 300A of a MEMS mirror device according to one or more implementations. The plurality of support structures 207 may have a lattice pattern that defines the plurality of cavities 208. For example, the plurality of support structures 207 may interconnected in a triangular pattern. The plurality of cavities 208 may be triangular cavities defined in areas between respective support structures of the plurality of support structures 207.

As indicated above, FIG. 3A is provided as an example. Other examples may differ from what is described with regard to FIG. 3A.

FIG. 3B shows a plan view (top view) of a second hollow core assembly 300B of a MEMS mirror device according to one or more implementations. The plurality of support structures 207 may be interconnected to form a honeycomb pattern. The plurality of cavities 208 may be hexagonal cavities defined in areas between respective support structures of the plurality of support structures 207.

As indicated above, FIG. 3B is provided as an example. Other examples may differ from what is described with regard to FIG. 3B.

FIG. 3C shows a plan view (top view) of a third hollow core assembly 300C of a MEMS mirror device according to one or more implementations. The plurality of support structures 207 may be vertical struts arranged to form a truss framework. In addition, the cavities of the plurality of cavities 208 may be uniform in size substantially throughout the third hollow core assembly 300C, with the exception of those cavities arranged at an outer edge of the third hollow core assembly 300C.

As indicated above, FIG. 3C is provided as an example. Other examples may differ from what is described with regard to FIG. 3C.

FIG. 3D shows a plan view (top view) of a fourth hollow core assembly 300D of a MEMS mirror device according to one or more implementations. The plurality of support structures 207 may be vertical struts arranged to form a truss framework. In addition, the cavities of the plurality of cavities 208 may be uniform in size substantially throughout the fourth hollow core assembly 300D, with the exception of those cavities arranged at an outer edge of the fourth hollow core assembly 300D. The plurality of cavities 208 include a first group of cavities 208a arranged in a central section 301 of the fourth hollow core assembly 300D and a second group of cavities 208b may be arranged in a peripheral section 302 of the fourth hollow core assembly 300D. Cavities of the first group of cavities 208a may be smaller in size than cavities of the second group of cavities 208b. As a result, the fourth hollow core assembly 300D may provide more rigidity or stiffness in the central section 301 of the mirror body 203 compared to a rigidity or stiffness in the peripheral section 302 of the mirror body 203 to reduce or prevent dynamic deformation where the dynamic deformation is most likely to occur.

In some implementations, a spacing of the plurality of support structures 207 may have a higher density in the central section 301 of the fourth hollow core assembly 300D than a relatively lower density in the peripheral section 302 of the fourth hollow core assembly 300D. As a result, the fourth hollow core assembly 300D may provide more rigidity or stiffness in the central are of the mirror body 203 compared to a rigidity or stiffness in the peripheral area of the mirror body 203.

In some implementations, the fourth hollow core assembly 300D may have a higher mass in a central section 301 of the fourth hollow core assembly 300D than a relatively lower mass in the peripheral section 302 of the fourth hollow core assembly 300D. As a result, the fourth hollow core assembly 300D may provide more rigidity or stiffness in the central section 301 of the mirror body 203 compared to a rigidity or stiffness in the peripheral section 302 of the mirror body 203.

In some implementations, cavities 208a of the plurality of cavities arranged in the central section 301 of the fourth hollow core assembly 300D may have smaller volumes relative to volumes of cavities 208b of the plurality of cavities arranged in the peripheral section 302 of the fourth hollow core assembly 300D. As a result, the fourth hollow core assembly 300D may provide more rigidity or stiffness in the central section 301 of the mirror body 203 compared to a rigidity or stiffness in the peripheral section 302 of the mirror body 203.

As indicated above, FIG. 3D is provided as an example. Other examples may differ from what is described with regard to FIG. 3D.

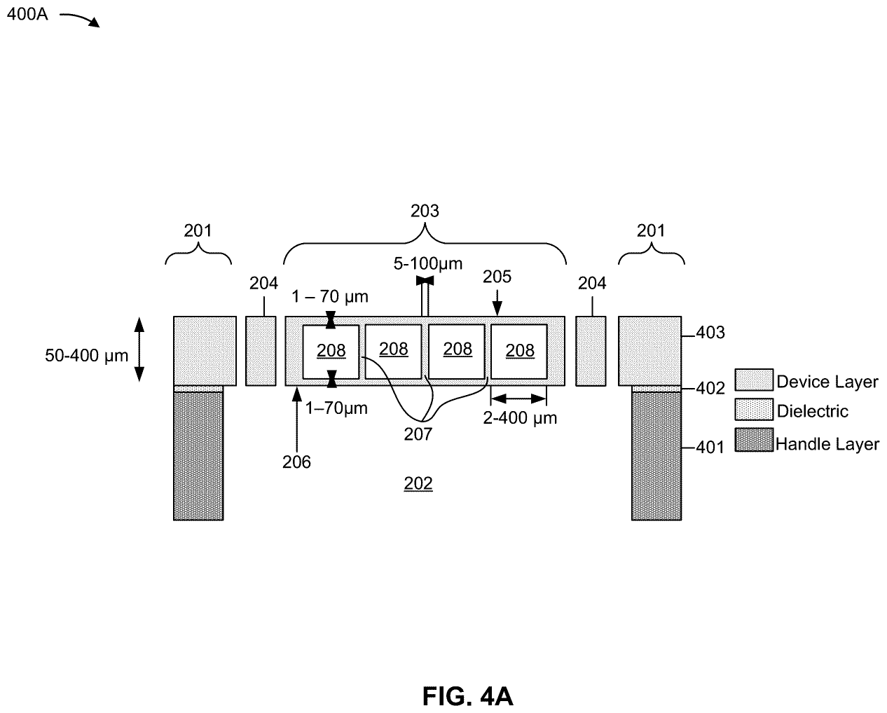

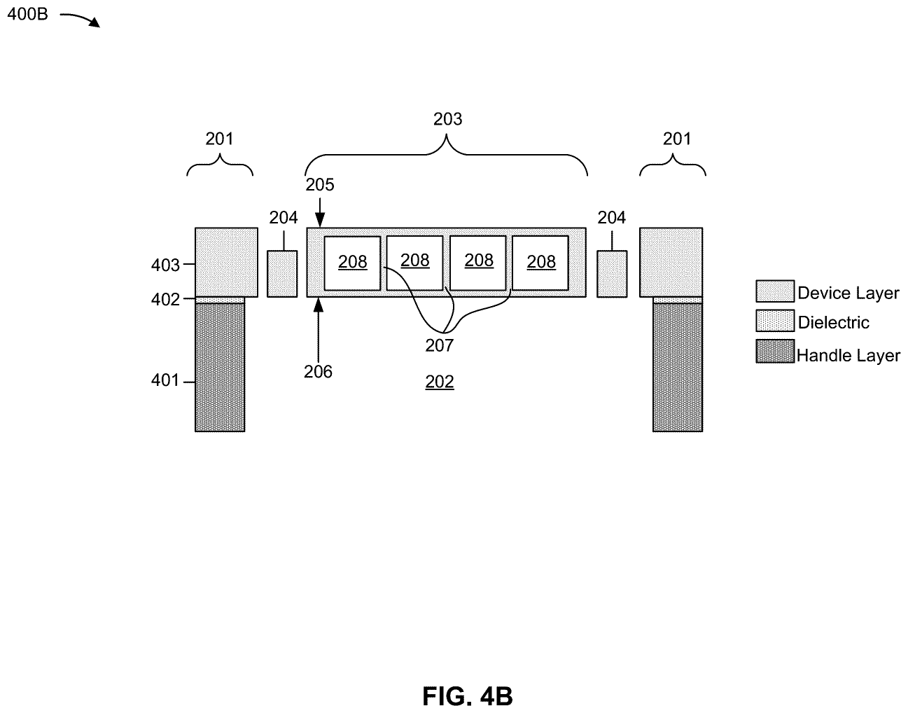

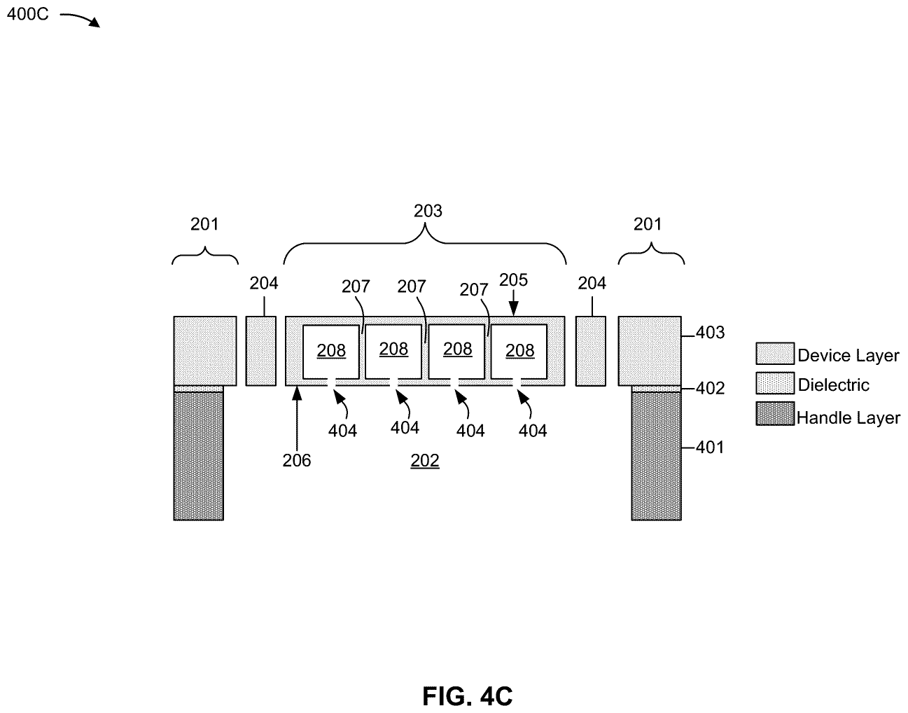

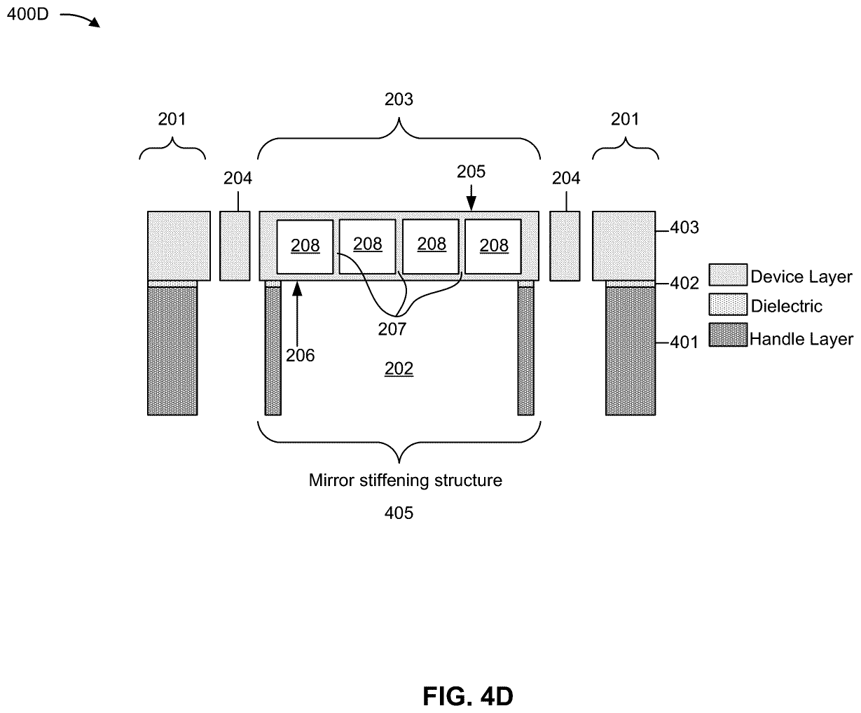

FIG. 4A shows a cross-section of a MEMS mirror device 400A according to one or more implementations. The MEMS mirror device 400A may be similar to the MEMS mirror device 200 described in connection with FIGS. 2A and 2B. Thus, the MEMS mirror device 400A includes a frame 201, a frame cavity 202, a mirror body 203, a suspension assembly including torsion bars 204, a front plate 205, a back plate 206, and a hollow core assembly formed by a plurality of support structures 207 that define a plurality of cavities 208. The MEMS mirror device 400A may include a handle layer 401, a dielectric layer 402, and a device layer 403 arranged in a layer stack formation. The handle layer 401 may be a semiconductor material (e.g., a silicon substrate) that may be etched to form the frame cavity 202. The dielectric layer 402 may serve as a protective layer during manufacturing of the MEMS mirror device 400A and may be any dielectric material, such as silicon oxide, silicon nitride, aluminum oxide, silicon carbide. The device layer 403 may also be a semiconductor material (e.g., silicon). The device layer 403 may be used to form an upper portion of the frame 201, the mirror body 203, and the suspension assembly (e.g., the torsion bars 204). Thus, the mirror body 203 and the suspension assembly may be made of silicon, with the mirror body 203 having a reflective layer (not illustrated) disposed on the front plate 205.

In some implementations, the mirror body 203 and the torsion bars 204 may have a same thickness (e.g., the mirror body 203 and the suspension assembly have a same thickness).

As indicated above, FIG. 4A is provided as an example. Other examples may differ from what is described with regard to FIG. 4A.

FIG. 4B shows a cross-section of a MEMS mirror device 400B according to one or more implementations. The MEMS mirror device 400B may be similar to the MEMS mirror device 40A described in connection with FIG. 4A, with the exception that the mirror body 203 and the torsion bars 204 have different thicknesses (e.g., the mirror body 203 and the suspension assembly have different thicknesses). For example, a thickness of the torsion bars 204 may be less than a thickness of the mirror body 203.

As indicated above, FIG. 4B is provided as an example. Other examples may differ from what is described with regard to FIG. 4B.

FIG. 4C shows a cross-section of a MEMS mirror device 400C according to one or more implementations. The MEMS mirror device 400C may be similar to the MEMS mirror device 400A described in connection with FIG. 4A, with the exception that the back plate 206 is a perforated back plate. The back plate 206 includes a plurality of perforations 404 that extend through the back plate 206. Each perforation 404 may be integrated with a respective cavity 208 of the hollow core assembly. The perforations 404 may be used to etch (e.g., to form) each cavity 208 and may reduce the mass of the mirror body 203.

As indicated above, FIG. 4C is provided as an example. Other examples may differ from what is described with regard to FIG. 4C.

FIG. 4D shows a cross-section of a MEMS mirror device 400D according to one or more implementations. The MEMS mirror device 400D may be similar to the MEMS mirror device 400A described in connection with FIG. 4A, with the exception that the MEMS mirror device 400D includes one or more stiffening support structures 405. The one or more stiffening support structures 405 may be coupled to the back plate 206 and may extend from the back plate 206 into the frame cavity 202. The one or more stiffening support structures 405 may be formed from the handle layer 410. The one or more stiffening support structures 405 may include a ring structure or one or more bars or plates. The one or more stiffening support structures 405 may be configured to reduce a dynamic deformation of the mirror body 203 during an oscillating operation.

A size of the one or more stiffening support structures 405 may allow different tuning of the inertia of the mirror body 203 that occurs during oscillation. The inertia may affect the oscillation (resonant) frequency and the maximum tilt amplitude of the mirror body 203. Thus, the tuning of the inertia may lead to the tuning of the oscillation frequency and the maximum tilt amplitude of the mirror body 203.

As indicated above, FIG. 4D is provided as an example. Other examples may differ from what is described with regard to FIG. 4D.

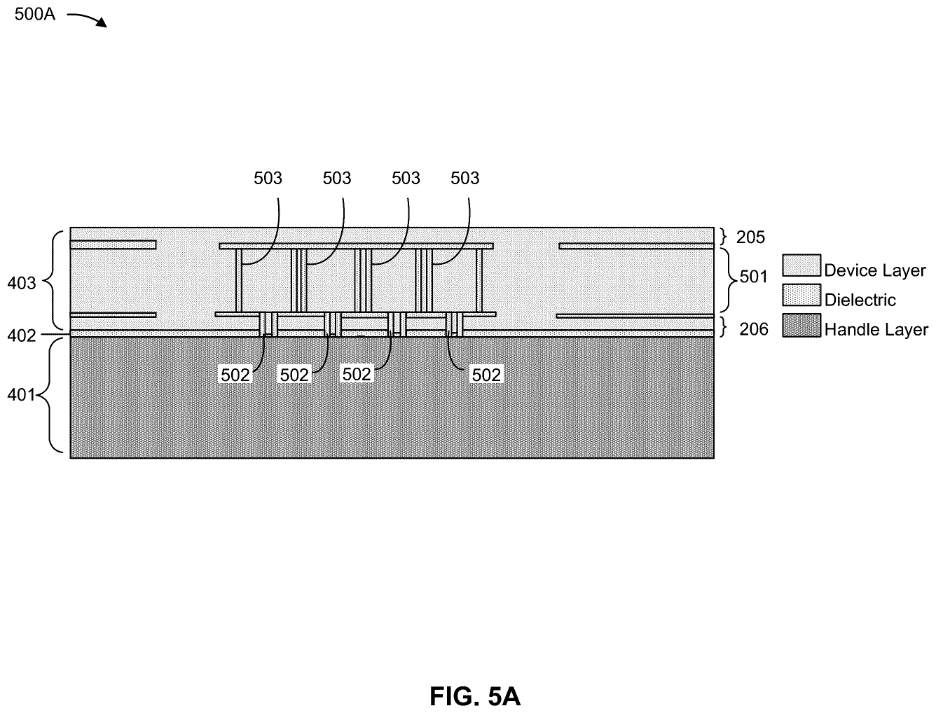

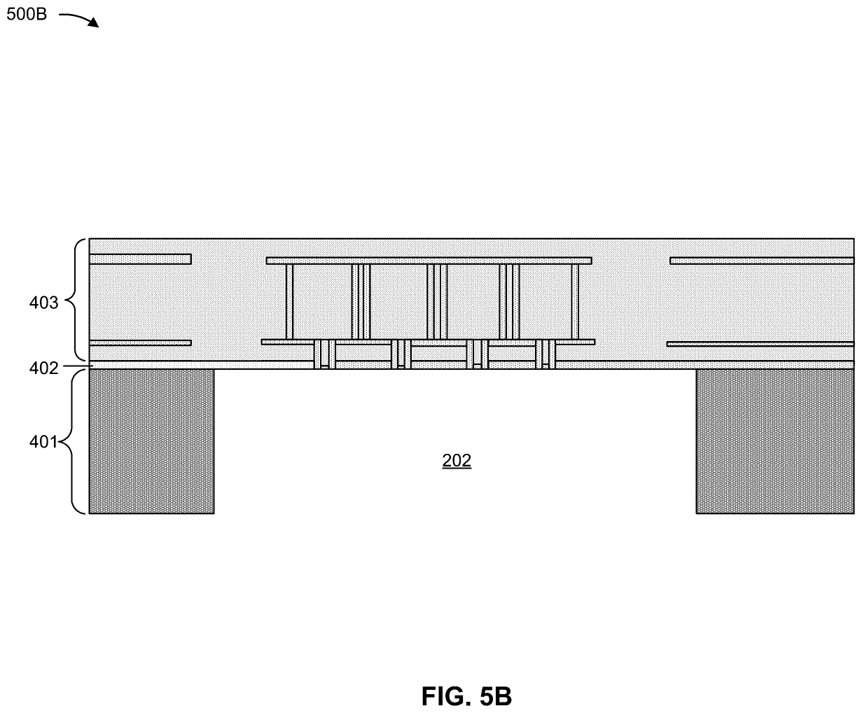

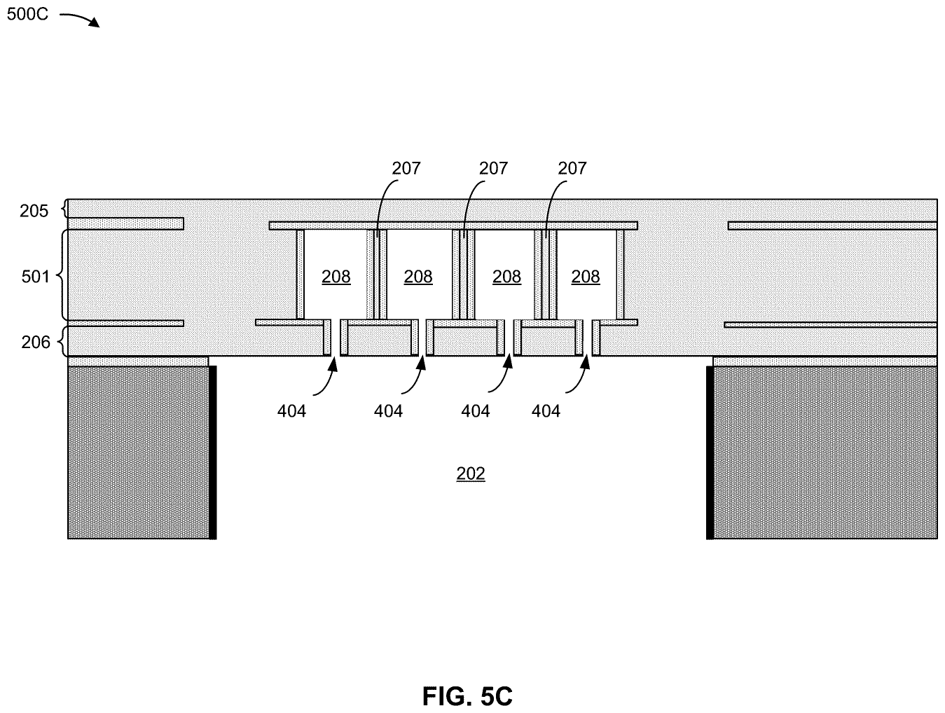

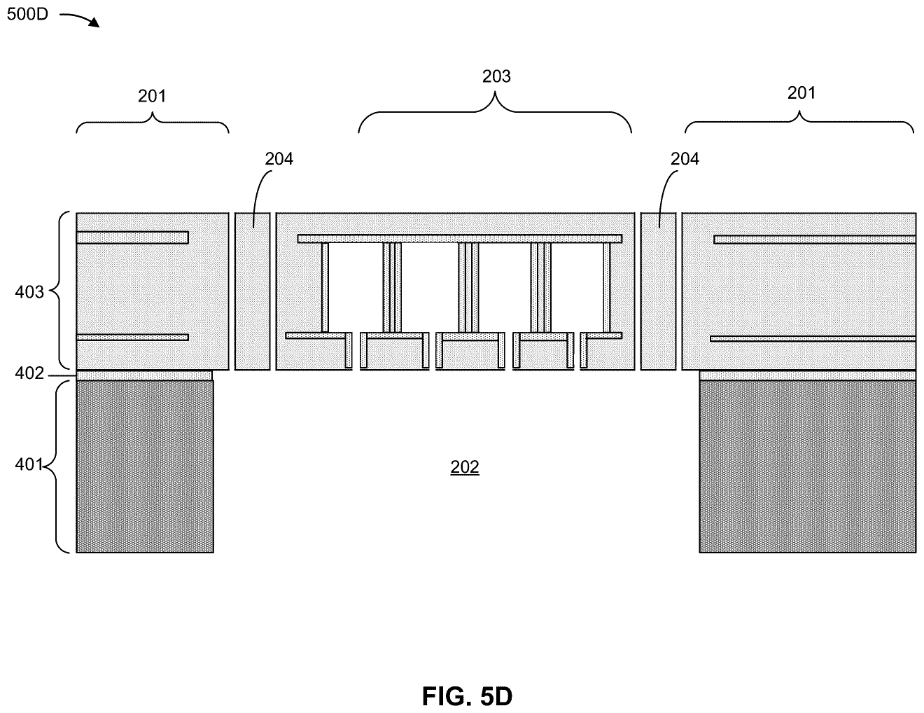

FIGS. 5A-5D show a process flow directed to a method of manufacturing a MEMS mirror device according to one or more implementations. FIG. 5A shows a first process stage 500A that includes forming a layer stack that includes handle layer 401 (e.g., a silicon substrate), a dielectric layer 402, and a device layer 403. The device layer 403 may include the back plate 206, a hollow core assembly 501, and the front plate 205 formed on the handle layer 401. The back plate 206 may be formed by one or more silicon layers and one or more protection layers (e.g., dielectric layers). The back plate 206 may include trenches 502 filled with protection layers. Portions of silicon of the back plate 206 may be etched to form perforations through the back plate 206. The perforations may be used to form the cavities 208. The hollow core assembly 501 may include one or more silicon layers and trenches 503 filled with protection layers. The front plate 205 may include one or more silicon layers.

FIG. 5B shows a second process stage 500B that includes etching the handle layer 401 to form the frame cavity.

FIG. 5C shows a third process stage 500C that includes forming perforations 404 through the back plate 406, forming the plurality of support structures 207, and forming cavities 208 within the hollow core assembly 501. The cavities 208 may be formed by isotropically etching the silicon layers of the back plate 406 and the hollow core assembly 501.

FIG. 5D shows a fourth process stage 500D that includes etching the suspension assembly in the device layer 403 (e.g., to form torsion bars 204). The etching may also define the frame 201 and the mirror body 203.

The sandwich structure of the hollow core assembly 501 may result in high-frequency MEMS micro-mirrors to have low dynamic deformation of the mirror body 203 during high-frequency (resonant) operation, which results in better optical resolution of the scanning mirror (e.g., for a laser beam scanning display).

As indicated above, FIGS. 5A-5D are provided as examples. Other examples may differ from what is described with regard to FIGS. 5A-5D.

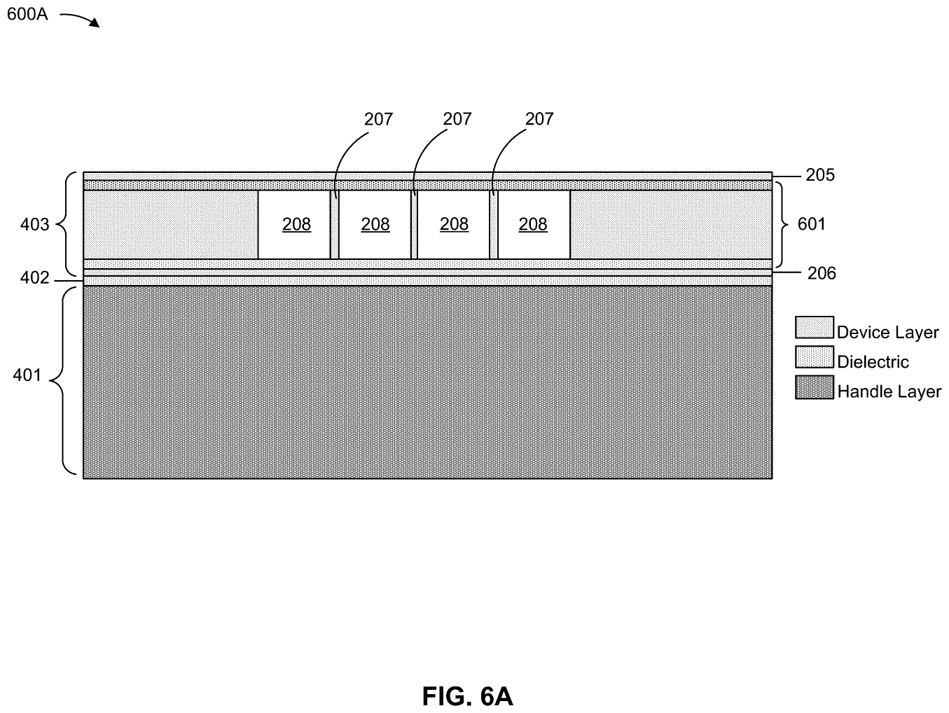

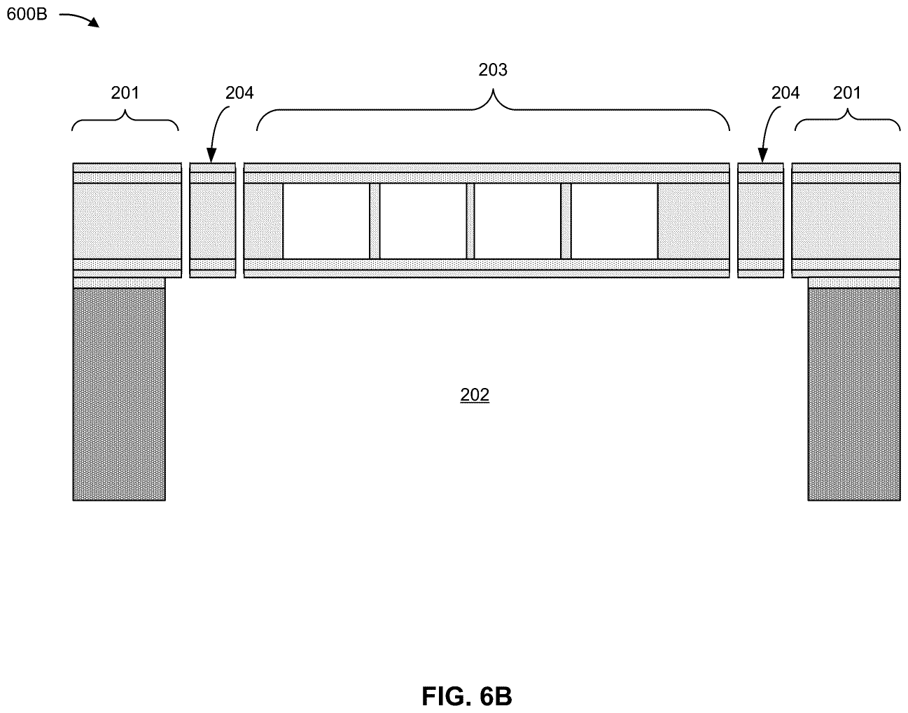

FIGS. 6A and 6B show a process flow directed to a method of manufacturing a MEMS mirror device according to one or more implementations. FIG. 6A shows a first process stage 600A that includes forming a layer stack that includes handle layer 401 (e.g., a silicon substrate), a dielectric layer 402, and a device layer 403. The device layer 403 may include the back plate 206, a hollow core assembly 601, and the front plate 205 formed on the handle layer 401. The back plate 206 may be formed by one or more silicon layers. The hollow core assembly 601 may include two dielectric layers and one or more silicon layers arranged between the two dielectric layers. The hollow core assembly 601 may be preformed (e.g., via etching) with the plurality of support structures 207 that define the plurality of cavities. The front plate 205 may include one or more silicon layers.

FIG. 6B shows a second process stage 600B that includes forming the frame cavity 202 and the suspension assembly (e.g., torsion bars 204) by etching. The etching may also define the frame 201 and the mirror body 203.

The sandwich structure of the hollow core assembly 601 may result in high-frequency MEMS micro-mirrors to have low dynamic deformation of the mirror body 203 during high-frequency (resonant) operation, which results in better optical resolution of the scanning mirror (e.g., for a laser beam scanning display).

As indicated above, FIGS. 6A and 6B are provided as examples. Other examples may differ from what is described with regard to FIGS. 6A and 6B.

The following provides an overview of some Aspects of the present disclosure:

Aspect 1: A MEMS mirror device, comprising: a frame that defines a frame cavity; a suspension assembly; and a mirror body coupled to the frame by the suspension assembly such that the mirror body is suspended over the frame cavity, wherein the mirror body comprises a sandwich structure that includes a front plate, a back plate, and a hollow core assembly arranged between the front plate and the back plate, wherein the front plate and the back plate define a thickness dimension of the mirror body, and wherein the hollow core assembly includes a plurality of support structures that extend between the front plate and the back plate and define a plurality of cavities between the front plate and the back plate.

Aspect 2: The MEMS mirror device of Aspect 1, wherein the plurality of support structures are interconnected to form a triangular pattern, and wherein the plurality of cavities are triangular cavities defined in areas between respective support structures of the plurality of support structures.

Aspect 3: The MEMS mirror device of any of Aspects 1-2, wherein the plurality of support structures are interconnected to form a honeycomb pattern, and wherein the plurality of cavities are hexagonal cavities defined in areas between respective support structures of the plurality of support structures.

Aspect 4: The MEMS mirror device of any of Aspects 1-3, wherein the plurality of support structures are interconnected to form a polygonal pattern, and wherein the plurality of cavities are polygonal cavities defined in areas between respective support structures of the plurality of support structures.

Aspect 5: The MEMS mirror device of any of Aspects 1-4, wherein the plurality of support structures are vertical struts arranged to form a truss framework or a lattice pattern that is integrated into the mirror body.

Aspect 6: The MEMS mirror device of any of Aspects 1-5, wherein cavities of the plurality of cavities are uniform in size throughout the hollow core assembly.

Aspect 7: The MEMS mirror device of any of Aspects 1-6, wherein the plurality of cavities include a first group of cavities arranged in a central section of the hollow core assembly and a second group of cavities are arranged in a peripheral section of the hollow core assembly, wherein cavities of the first group of cavities are smaller in size than cavities of the second group of cavities.

Aspect 8: The MEMS mirror device of any of Aspects 1-7, wherein a spacing of the plurality of support structures has a higher density in a central area of the mirror body than a relatively lower density in a peripheral area of the mirror body.

Aspect 9: The MEMS mirror device of any of Aspects 1-8, wherein the hollow core assembly has a higher mass in a central area of the mirror body than a relatively lower mass in a peripheral area of the mirror body.

Aspect 10: The MEMS mirror device of any of Aspects 1-9, wherein cavities of the plurality of cavities arranged in a central area of the mirror body have smaller volumes relative to volumes of cavities of the plurality of cavities arranged in a peripheral area of the mirror body.

Aspect 11: The MEMS mirror device of any of Aspects 1-10, wherein the mirror body is configured to oscillate about one or more rotational axes, and wherein the plurality of support structures are configured to reduce a dynamic deformation of the mirror body during oscillation of the mirror body about the one or more rotational axes.

Aspect 12: The MEMS mirror device of Aspect 11, wherein the plurality of support structures are configured such that a volume of the plurality of cavities enables the mirror body to oscillate at a resonant frequency that is greater than 10 KHz.

Aspect 13: The MEMS mirror device of Aspect 11, wherein the plurality of support structures are configured such that a mass of the plurality of support structures enables the mirror body to oscillate at a resonant frequency that is greater than 10 kHz with a maximum amplitude that is greater than 10°.

Aspect 14: The MEMS mirror device of any of Aspects 1-13, wherein the hollow core assembly is configured to enable the mirror body to oscillate at a resonant frequency greater than 10 kHz with reduced inertia and reduced dynamic deformation.

Aspect 15: The MEMS mirror device of Aspect 14, wherein the thickness dimension of the mirror body is between 50-400 μm and each support structure of the plurality of support structures has a width dimension between 5-100 μm.

Aspect 16: The MEMS mirror device of Aspect 14, wherein the front plate and the back plate each have a thickness dimension between 1-70 μm.

Aspect 17: The MEMS mirror device of Aspect 14, wherein each cavity of the plurality of cavities has a width between 2-400 μm.

Aspect 18: The MEMS mirror device of Aspect 14, wherein each support structure of the plurality of support structures has a thickness dimension extending between the front plate and the back plate and a width dimension perpendicular to the thickness dimension, and wherein a ratio of the width dimension and the thickness dimension of each support structure is in a range of 1:8 to 1:200.

Aspect 19: The MEMS mirror device of any of Aspects 1-18, wherein the back plate is a perforated back plate having a plurality of perforations that extend through the back plate.

Aspect 20: The MEMS mirror device of Aspect 19, wherein each perforation of the plurality of perforations is integrated with a respective cavity of the plurality of cavities.

Aspect 21: The MEMS mirror device of Aspect 19, wherein each cavity of the plurality of cavities is integrated with a respective perforation of the plurality of perforations.

Aspect 22: The MEMS mirror device of any of Aspects 1-21, further comprising: one or more stiffening support structures coupled to the back plate and extending from the back plate into the frame cavity, wherein the one or more stiffening support structures are configured to reduce a dynamic deformation of the mirror body during an oscillating operation.

Aspect 23: The MEMS mirror device of any of Aspects 1-22, wherein the front plate, the back plate, and the hollow core assembly form a one-piece integral member.

Aspect 24: An oscillator device, comprising: a frame that defines a frame cavity; a suspension assembly; and an oscillator body coupled to the frame by the suspension assembly such that the oscillator body is suspended over the frame cavity, wherein the oscillator body is configured to oscillate about one or more rotational axes, wherein the oscillator body comprises a sandwich structure that includes a front plate, a back plate arranged opposite to the front plate, and a hollow core assembly arranged between the front plate and the back plate, wherein the hollow core assembly includes a plurality of support structures that extend between the front plate and the back plate and define a plurality of cavities between the front plate and the back plate, and wherein the hollow core assembly is configured to reduce a dynamic deformation of the oscillator body during oscillation of the oscillator body about the one or more rotational axes and enable the oscillator body to oscillate at a resonant frequency that is greater than 10 KHz.

Aspect 25: A system configured to perform one or more operations recited in one or more of Aspects 1-24.

Aspect 26: An apparatus comprising means for performing one or more operations recited in one or more of Aspects 1-24.

The foregoing disclosure provides illustration and description, but is not intended to be exhaustive or to limit the implementations to the precise form disclosed. Modifications and variations may be made in light of the above disclosure or may be acquired from practice of the implementations.

For example, although implementations described herein relate to MEMS devices with a mirror, it is to be understood that other implementations may include optical devices other than MEMS mirror devices or other MEMS oscillating structures. In addition, although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer, or an electronic circuit.

Some implementations may be described herein in connection with thresholds. As used herein, “satisfying” a threshold may refer to a value being greater than the threshold, more than the threshold, higher than the threshold, greater than or equal to the threshold, less than the threshold, fewer than the threshold, lower than the threshold, less than or equal to the threshold, equal to the threshold, or the like.

As used herein, the term “component” is intended to be broadly construed as hardware, firmware, or a combination of hardware and software. It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code-it being understood that software and hardware can be designed to implement the systems and/or methods based on the description herein.

Any of the processing components may be implemented as a central processing unit (CPU) or other processor reading and executing a software program from a non-transitory computer-readable recording medium such as a hard disk or a semiconductor memory device. For example, instructions may be executed by one or more processors, such as one or more CPUs, digital signal processors (DSPs), general-purpose microprocessors, application-specific integrated circuits (ASICs), field programmable logic arrays (FPLAs), programmable logic controller (PLC), or other equivalent integrated or discrete logic circuitry. Accordingly, the term “processor,” as used herein refers to any of the foregoing structures or any other structure suitable for implementation of the techniques described herein. Software may be stored on a non-transitory computer-readable medium such that the non-transitory computer readable medium includes a program code or a program algorithm stored thereon which, when executed, causes the processor, via a computer program, to perform the steps of a method.

A controller including hardware may also perform one or more of the techniques of this disclosure. A controller, including one or more processors, may use electrical signals and digital algorithms to perform its receptive, analytic, and control functions, which may further include corrective functions. Such hardware, software, and firmware may be implemented within the same device or within separate devices to support the various techniques described in this disclosure.

A signal processing circuit and/or a signal conditioning circuit may receive one or more signals (e.g., measurement signals) from one or more components in the form of raw measurement data and may derive, from the measurement signal further information. Signal conditioning, as used herein, refers to manipulating an analog signal in such a way that the signal meets the requirements of a next stage for further processing. Signal conditioning may include converting from analog to digital (e.g., via an analog-to-digital converter), amplification, filtering, converting, biasing, range matching, isolation and any other processes required to make a signal suitable for processing after conditioning.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a and b, a and c, b and c, and a, b, and c, as well as any combination with multiples of the same element (e.g., a+a, a+a+a, a+a+b, a+a+c, a+b+b, a+c+c, b +b, b +b +b, b+b+c, c +c, and c +c +c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

Further disclosure is included in the appendix. The appendix is provided as an example only and is to be considered part of the specification. A definition, illustration, or other description in the appendix does not supersede or override similar information included in the detailed description or figures. Furthermore, a definition, illustration, or other description in the detailed description or figures does not supersede or override similar information included in the appendix. Furthermore, the appendix is not intended to limit the disclosure of possible implementations.

What is claimed is:

1. A microelectromechanical system (MEMS) mirror device, comprising:
a frame that defines a frame cavity;
a suspension assembly; and
a mirror body coupled to the frame by the suspension assembly such that the mirror body is suspended over the frame cavity,
wherein the mirror body comprises a sandwich structure that includes a front plate, a back plate, and a hollow core assembly arranged between the front plate and the back plate,
wherein the front plate and the back plate define a thickness dimension of the mirror body, and
wherein the hollow core assembly includes a plurality of support structures that extend between the front plate and the back plate and define a plurality of cavities between the front plate and the back plate.

2. The MEMS mirror device of claim 1, wherein the plurality of support structures are interconnected to form a triangular pattern, and
wherein the plurality of cavities are triangular cavities defined in areas between respective support structures of the plurality of support structures.

3. The MEMS mirror device of claim 1, wherein the plurality of support structures are interconnected to form a honeycomb pattern, and
wherein the plurality of cavities are hexagonal cavities defined in areas between respective support structures of the plurality of support structures.

4. The MEMS mirror device of claim 1, wherein the plurality of support structures are interconnected to form a polygonal pattern, and
wherein the plurality of cavities are polygonal cavities defined in areas between respective support structures of the plurality of support structures.

5. The MEMS mirror device of claim 1, wherein the plurality of support structures are vertical struts arranged to form a truss framework or a lattice pattern that is integrated into the mirror body.

6. The MEMS mirror device of claim 1, wherein cavities of the plurality of cavities are uniform in size throughout the hollow core assembly.

7. The MEMS mirror device of claim 1, wherein the plurality of cavities include a first group of cavities arranged in a central section of the hollow core assembly and a second group of cavities are arranged in a peripheral section of the hollow core assembly, wherein cavities of the first group of cavities are smaller in size than cavities of the second group of cavities.

8. The MEMS mirror device of claim 1, wherein a spacing of the plurality of support structures has a higher density in a central area of the mirror body than a relatively lower density in a peripheral area of the mirror body.

9. The MEMS mirror device of claim 1, wherein the hollow core assembly has a higher mass in a central area of the mirror body than a relatively lower mass in a peripheral area of the mirror body.

10. The MEMS mirror device of claim 1, wherein cavities of the plurality of cavities arranged in a central area of the mirror body have smaller volumes relative to volumes of cavities of the plurality of cavities arranged in a peripheral area of the mirror body.

11. The MEMS mirror device of claim 1, wherein the mirror body is configured to oscillate about one or more rotational axes, and
wherein the plurality of support structures are configured to reduce a dynamic deformation of the mirror body during oscillation of the mirror body about the one or more rotational axes.

12. The MEMS mirror device of claim 11, wherein the plurality of support structures are configured such that a volume of the plurality of cavities enables the mirror body to oscillate at a resonant frequency that is greater than 10 kHz.

13. The MEMS mirror device of claim 11, wherein the plurality of support structures are configured such that a mass of the plurality of support structures enables the mirror body to oscillate at a resonant frequency that is greater than 10 kHz with a maximum amplitude that is greater than 10°.

14. The MEMS mirror device of claim 1, wherein the hollow core assembly is configured to enable the mirror body to oscillate at a resonant frequency greater than 10 kHz with reduced inertia and reduced dynamic deformation.

15. The MEMS mirror device of claim 14, wherein the thickness dimension of the mirror body is between 50-400 μm and each support structure of the plurality of support structures has a width dimension between 5-100 μm.

16. The MEMS mirror device of claim 14, wherein the front plate and the back plate each have a thickness dimension between 1-70 μm.

17. The MEMS mirror device of claim 14, wherein each cavity of the plurality of cavities has a width between 2-400 μm.

18. The MEMS mirror device of claim 14, wherein each support structure of the plurality of support structures has a thickness dimension extending between the front plate and the back plate and a width dimension perpendicular to the thickness dimension, and wherein a ratio of the width dimension and the thickness dimension of each support structure is in a range of 1:8 to 1:200.

19. The MEMS mirror device of claim 1, wherein the back plate is a perforated back plate having a plurality of perforations that extend through the back plate.

20. The MEMS mirror device of claim 19, wherein each perforation of the plurality of perforations is integrated with a respective cavity of the plurality of cavities.

21. The MEMS mirror device of claim 19, wherein each cavity of the plurality of cavities is integrated with a respective perforation of the plurality of perforations.

22. The MEMS mirror device of claim 1, further comprising:
one or more stiffening support structures coupled to the back plate and extending from the back plate into the frame cavity,
wherein the one or more stiffening support structures are configured to reduce a dynamic deformation of the mirror body during an oscillating operation.

23. The MEMS mirror device of claim 1, wherein the front plate, the back plate, and the hollow core assembly form a one-piece integral member.

24. An oscillator device, comprising:
a frame that defines a frame cavity;
a suspension assembly; and
an oscillator body coupled to the frame by the suspension assembly such that the oscillator body is suspended over the frame cavity,
wherein the oscillator body is configured to oscillate about one or more rotational axes,
wherein the oscillator body comprises a sandwich structure that includes a front plate, a back plate arranged opposite to the front plate, and a hollow core assembly arranged between the front plate and the back plate,
wherein the hollow core assembly includes a plurality of support structures that extend between the front plate and the back plate and define a plurality of cavities between the front plate and the back plate, and
wherein the hollow core assembly is configured to reduce a dynamic deformation of the oscillator body during oscillation of the oscillator body about the one or more rotational axes and enable the oscillator body to oscillate at a resonant frequency that is greater than 10 kHz.
